(19) United States
(12) Patent Application Publication
(10) Pub. No.: US 2025/0337386 A1
(43) Pub. Date: Oct. 30, 2025

(54) RESONANCE DEVICE AND METHOD FOR MANUFACTURING SAME

(71) Applicant: Murata Manufacturing Co., Ltd., Nagaokakyo-shi, Kyoto-fu (JP)

(72) Inventors: Masakazu FUKUMITSU, Nagaokakyo-shi, Kyoto-fu (JP); Yoshiyuki HIGUCHI, Nagaokakyo-shi, Kyoto-fu (JP); Fumiya ENDO, Nagaokakyo-shi, Kyoto-fu (JP)

(21) Appl. No.: 18/958,280

(22) Filed: Nov. 25, 2024

Related U.S. Application Data
(63) Continuation of application No. PCT/JP2023/007204, filed on Feb. 28, 2023.

(30) Foreign Application Priority Data
Jul. 5, 2022 (JP) 2022-108105

(51) Int. Cl. H03H 9/05; H03H 3/007; H03H 9/56

(52) U.S. Cl. CPC H03H 9/0595; H03H 3/0077; H03H 9/564

(57) ABSTRACT

A resonance device includes: a resonator and a first substrate. The resonator includes a vibration part, a frame disposed at at least a portion of a circumference of the vibration part, and a supporting arm configured to connect the vibration part and the frame. The first substrate includes a first bottom plate configured to have a first gap to the vibration part in a thickness direction. The vibration part includes a vibration arm configured to perform out-of-plane bending vibration. The vibration arm includes a tip-end part with a base-end-side portion and a tip-end-side portion that is closer to an open-end side of the vibration arm than the base-end-side portion, the base-end-side portion has a first surface that includes a metal film facing the first bottom plate, the tip-end-side portion has a second surface that includes silicon facing the first bottom plate.

### CROSS REFERENCE TO RELATED APPLICATIONS

This application is a continuation of International Application No. PCT/JP2023/007204, filed February 28,2023, which claims priority to Japanese Patent Application No. 2022-108105, filed Jul. 5, 2022, the contents of each of which are hereby incorporated by reference in their entireties.

### TECHNICAL FIELD

The present disclosure relates to a resonance device and a method for manufacturing the resonance device.

### BACKGROUND

In various electronic devices (for example, a mobile communication terminal, a communication base station, and a home appliance), resonance devices are used for various uses, such as a timing device, a sensor, and an oscillator. As one type of these resonance devices, a so-called micro electromechanical systems (MEMS) resonance device including a lower cover, an upper cover, and a resonator has been known. The upper cover forms a vibration space between the lower cover and the upper cover. The resonator includes a vibration arm held in the vibration space in a vibratable manner.

For example, International Publication No. 2021-117272 discloses a resonance device including a lower cover, an upper cover, and a resonator including a vibration arm that is capable of bending vibration. The vibration arm has a tip-end part provided with a metal film at a side that faces the upper cover. A gap between the tip-end part of the vibration arm and the upper cover is larger than a gap between the tip-end part of the vibration arm and the lower cover.

However, in the resonance device described in International Publication No. 2021-117272, when a resonant frequency is adjusted by the vibration arm being collided with the lower cover or the upper cover, an impact caused by collision between the vibration arm and the upper cover can be absorbed by the metal film. In such a case, if the gap between the tip-end part of the vibration arm and the upper cover is increased to avoid the collision between the vibration arm and the upper cover, the upper cover has an increased height. This configuration can restrict the size of the resonance device from being decreased.

### SUMMARY OF THE INVENTION

The present disclosure is made in view of the circumstance, and one of the objects thereof is to provide a resonance device having a reduced size and a method for manufacturing the resonance device according to some exemplary aspects.

In an exemplary aspect, a resonance device is provided that includes: a resonator and a first substrate. The resonator includes a vibration part, a holding part or a frame that is disposed at at least a portion of a circumference of the vibration part, and a supporting arm configured to connect the vibration part to the holding part. The first substrate includes a first bottom plate configured to have a first gap to the vibration part in a thickness direction, and a first side wall extending from a circumferential edge of the first bottom plate toward the holding part. The vibration part includes a vibration arm configured to perform out-of-plane bending vibration. The vibration arm includes a tip-end with a base-end-side portion and a tip-end-side portion that is closer to an open-end side of the vibration arm than the base-end-side portion, the base-end-side portion has a first surface that includes a metal film facing the first bottom plate. The tip-end-side portion has a second surface that includes silicon facing the first bottom plate.

In another exemplary aspect, a method for manufacturing the resonance device is provided. The method includes: preparing the resonator; preparing the first substrate; joining the resonator to the first substrate; and adjusting a frequency of the resonator by exciting the resonator to cause the tip-end-side portion to contact the first bottom plate.

According to the exemplary aspects of the present disclosure, a resonance device having a reduced size and a method for manufacturing the resonance device is provided.

### BRIEF DESCRIPTION OF DRAWINGS

FIG. 1 is a perspective view of a resonance device according to a first exemplary embodiment.

FIG. 2 is an exploded perspective view of the resonance device according to the first exemplary embodiment.

FIG. 3 is a plan view of an internal portion of the resonance device according to the first exemplary embodiment.

FIG. 4 is a sectional view of the resonance device according to the first exemplary embodiment.

FIG. 5 is a flowchart illustrating a method for manufacturing the resonance device according to the first exemplary embodiment.

FIG. 6 is a sectional view of a resonance device according to a second exemplary embodiment.

FIG. 7 is a sectional view of a resonance device according to a third exemplary embodiment.

FIG. 8 is a sectional view of a resonance device according to a fourth exemplary embodiment.

FIG. 9 is a flowchart illustrating a method for manufacturing the resonance device according to the fourth exemplary embodiment.

### DETAILED DESCRIPTION OF EXEMPLARY EMBODIMENTS

Hereinafter, exemplary embodiments of the present disclosure are described with reference to the drawings. The drawings of the present exemplary embodiments are merely illustration, where the dimensions and shapes of respective parts are schematic, and thereby the technical scope of the disclosure of the present application should not be interpreted as being limited to the exemplary embodiments.

### First Exemplary Embodiment

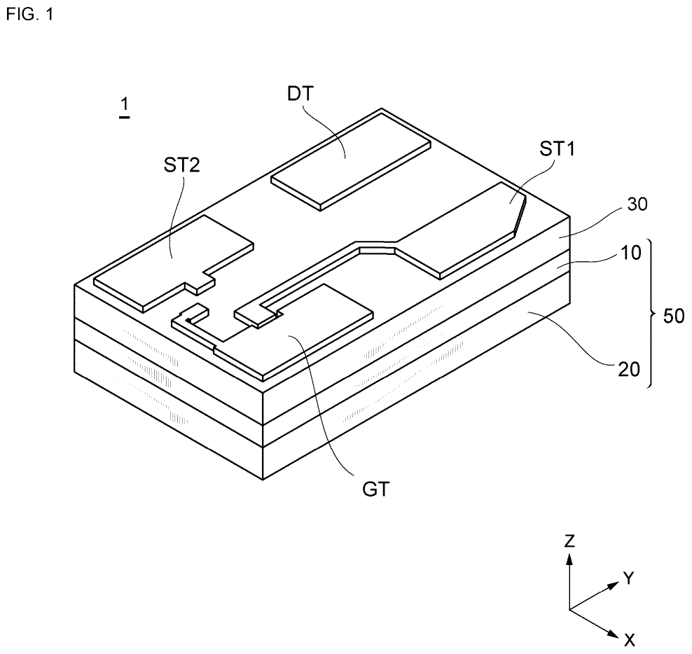

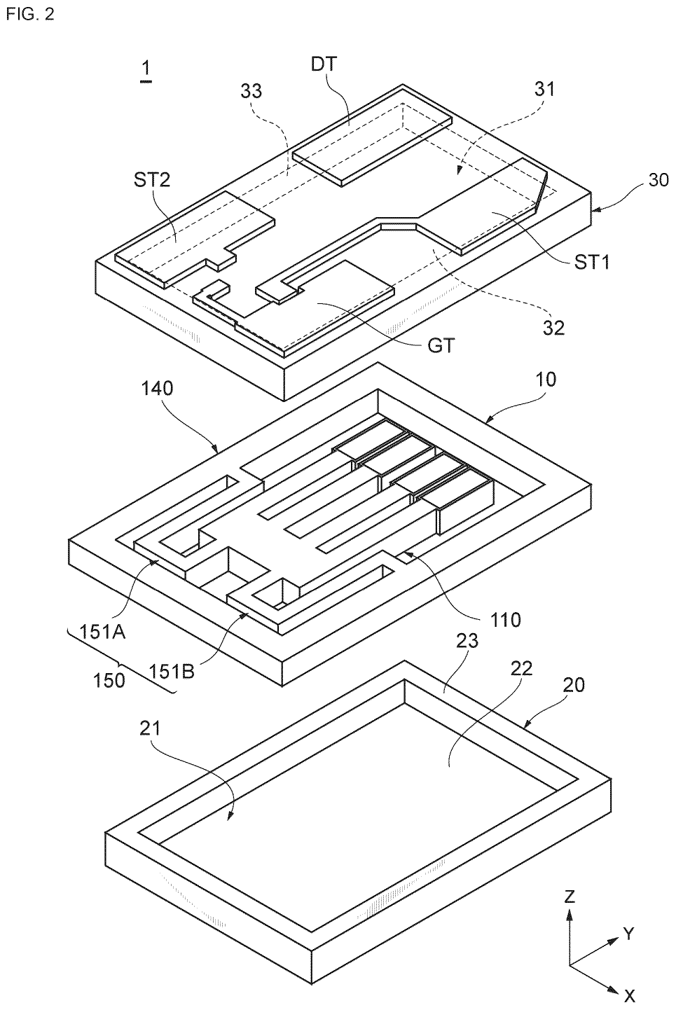

First, a schematic configuration of a resonance device 1 according to a first exemplary embodiment of the present disclosure is described with reference to FIGS. 1 and 2. FIG. 1 is a perspective view of the resonance device according to the first exemplary embodiment. FIG. 2 is an exploded perspective view of the resonance device according to the first exemplary embodiment.

Each configuration of the resonance device 1 is described below. In each drawing, the orthogonal coordinate system formed by the X-axis, the Y-axis, and the Z-axis can be given for the sake of convenience to clarify the mutual relationship between the drawings and to facilitate understanding on the positional relationship between the respective components. For purposes of this disclosure, respective directions in parallel to the X-axis, the Y-axis, and the Z-axis are referred to as an X-axis direction, a Y-axis direction, and a Z-axis direction. Moreover, a plane defined by the X-axis and the Y-axis is referred to as an XY plane, and the same holds for a YZ plane and a ZX plane.

As shown, the exemplary resonance device 1 includes a resonator 10, a lower cover 20, and an upper cover 30. The lower cover 20, the resonator 10, and the upper cover 30 are stacked in this order in the Z-axis direction. For purposes of this disclosure, the Z-axis direction in which the lower cover 20, the resonator 10, and the upper cover 30 are stacked is referred to below as a “thickness direction”. The resonator 10 and the lower cover 20 are joined one another to form a MEMS substrate 50. The upper cover 30 is joined to the resonator 10 of the MEMS substrate 50. In other words, the upper cover 30 is joined to the lower cover 20 with the resonator 10 interposed therebetween. The lower cover 20 and the upper cover 30 are opposed to one another in the thickness direction while sandwiching the resonator 10 therebetween. The lower cover 20 and the upper cover 30 form a package structure that internally forms a vibration space where the resonator 10 vibrates. According to an exemplary aspect, the upper cover 30 corresponds to one example of a first substrate, and the lower cover 20 corresponds to one example of a second substrate.

Moreover, the resonator 10 is a MEMS vibration element that is manufactured by using a MEMS technology. frequency band of the resonator 10 is, for example, 1 kHz or more and 1 MHz or less. The resonator 10 includes a vibration part 110, a holding part 140, and a supporting arm 150.

According to the exemplary aspect, the vibration part 110 is held in a vibratable manner in the vibration space provided between the lower cover 20 and the upper cover 30. The vibration part 110 extends along the XY plane in a non-vibrating state where no voltage is applied, and bending-vibrates in the Z-axis direction in a vibrating state where voltage is applied. That is, a vibration mode of the vibration part 110 is an out-of-plane bending vibration mode. However, the vibration part 110 in the non-vibrating state can bend in the Z direction due to its own weight.

It is noted that the vibration mode of the vibration part is not limited to the out-of-plane bending vibration mode. For example, the vibration mode of the vibration part can be an in-plane bending vibration mode, or can be a thickness-shear vibration mode in alternative exemplary aspects.

According to the exemplary aspect, the holding part 140 (e.g., a frame) is provided in a frame shape so as to surround the vibration part 110 when the XY plane is seen in plan view (hereinafter, simply be referred to as “in plan view”). The holding part 140 or frame forms, together with the lower cover 20 and the upper cover 30, the vibration space of the package structure. It is noted that the holding part 140 is not limited to having the frame shape as long as it is provided to at least a part of the circumference of the vibration part 110.

The supporting arm 150 is provided between the vibration part 110 and the holding part 140 when seen in plan view. The supporting arm 150 connects the vibration part 110 to the holding part 140.

The lower cover 20 includes a bottom plate 22 and a side wall 23. The bottom plate 22 is configured to have a gap with respect to the vibration part 110 in the thickness direction. The bottom plate 22 is a plate-shaped portion having a principal surface extending along the XY plane. The side wall 23 extends from a circumferential edge part of the bottom plate 22 toward the upper cover 30. The side wall 23 is a frame-shaped portion surrounding the vibration part 110 when seen in plan view. The side wall 23 is joined to the holding part 140 of the resonator 10. In the lower cover 20, a cavity 21 surrounded by the bottom plate 22 and the side wall 23 is formed at a side facing the vibration part 110 of the resonator 10. The cavity 21 is a cavity having a rectangular parallelepiped shape that opens toward the vibration part 110.

The upper cover 30 includes a bottom plate 32 and a side wall 33. The bottom plate 32 is configured to have a gap with respect to the vibration part 110 in the thickness direction. The bottom plate 32 is a plate-shaped portion having a principal surface extending along the XY plane. The side wall 33 extends from a circumferential edge part of the bottom plate 32 toward the lower cover 20. The side wall 33 is a frame-shaped portion surrounding the vibration part 110 when seen in plan view. The side wall 33 is joined to the holding part 140 of the resonator 10. In the upper cover 30, a cavity 31 surrounded by the bottom plate 32 and the side wall 33 is formed at a side facing the vibration part 110 of the resonator 10. The cavity 31 is a cavity having a rectangular parallelepiped shape that opens toward the vibration part 110. The cavity 21 and the cavity 31 face one another while sandwiching the vibration part 110 therebetween and form the vibration space of the resonator 10.

The upper cover 30 is provided with, at its upper surface, two power terminals ST1 and ST2, a ground terminal GT, and a dummy terminal DT. For purposes of this disclosure, the power terminals ST1 and ST2, the ground terminal GT, and the dummy terminal DT are collectively referred to below as an “outer terminal”. In operation, the power terminals ST1 and ST2 apply a drive signal (e.g., a drive voltage) to the resonator 10. The power terminals ST1 and ST2 are electrically connected to a metal film E2 that corresponds to an upper electrode of the resonator 10, which will be described later. The ground terminal GT applies a reference potential to the resonator 10. The ground terminal GT is electrically connected to a metal film El that corresponds to a lower electrode of the resonator 10, which will be described later. The dummy terminal DT is for, for example, balancing electric characteristics, such as electrostatic capacity, and balancing mechanical strength. The dummy terminal DT is not electrically connected to the resonator 10 in the exemplary aspect.

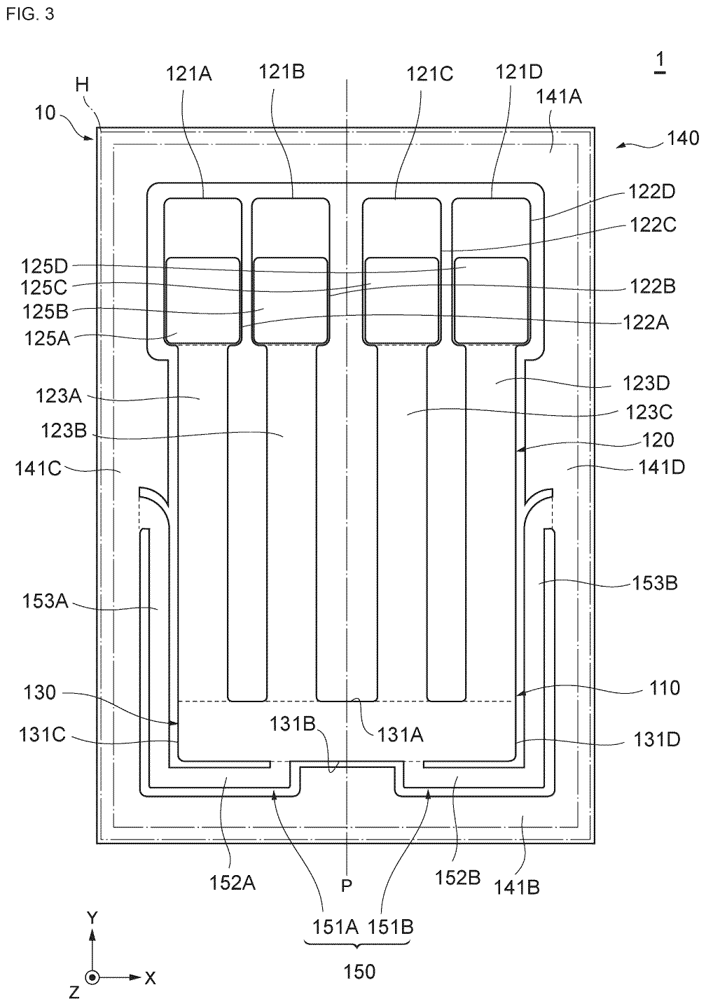

Next, schematic configurations of the vibration part 110, the holding part or frame 140, and the supporting arm 150 of the resonator 10 when seen in plan view are described with reference to FIG. 3. FIG. 3 is a plan view of an internal portion of the resonance device according to the first exemplary embodiment. It is noted that FIG. 3 shows the shape of the resonator 10 when seen in plan view from the upper cover 30 side. For purposes of this disclosure, the dimension in the Y-axis direction is referred to as the “length”, and the dimension in the X-axis direction is referred to as the “width”.

For example, the resonator 10 is formed plane-symmetrically with respect to an imaginary plane P that is in parallel to the YZ plane. That is, the shape of each of the vibration part 110, the holding part 140, and the supporting arm 150 is formed substantially plane-symmetrically with respect to the imaginary plane P.

As illustrated in FIG. 3, the vibration part 110 includes an excitation part 120 including four vibration arms 121A, 121B, 121C, and 121D, and a base part 130 connected to the excitation part 120. However, it is noted that the number of the vibration arms is not limited to four, but can be set to any number of one or more in alternative exemplary aspects. In the present exemplary embodiment, the excitation part 120 and the base part 130 are formed integrally. The vibration part 110 and the holding part 140 has a space formed therebetween with a given gap.

The vibration arms 121A to 121D each extends in the Y-axis direction, and they are aligned in this order in the X-axis direction having a given gap therebetween. The vibration arms 121A to 121D include a fixed end connected to the base part 130, and an open end farthest from the base part 130. The vibration arms 121A to 121D respectively include tip-end parts 122A to 122D provided at the open-end side, and arm parts 123A to 123D provided at the fixed-end side. The tip-end parts 122A to 122D have larger displacement than the arm parts 123A to 123D at the time of normal operation of the resonance device 1. The arm parts 123A to 123D connect the base part 130 and the tip-end parts 122A to 122D. The imaginary plane P is located between the vibration arm 121B and the vibration arm 121C.

Among the four vibration arms 121A to 121D, the two vibration arms 121A and 121D are considered outer vibration arms disposed at an outer side in the X-axis direction, and the two vibration arms 121B and 121C are considered inner vibration arms disposed at an inner side in the X-axis direction. The inner vibration arm 121B and the inner vibration arm 121C have a mutually symmetrical structure with respect to the imaginary plane P, and the outer vibration arm 121A and the outer vibration arm 121D have a mutually symmetrical structure with respect to the imaginary plane P.

The tip-end parts 122A to 122D respectively include metal films 125A to 125D on surfaces at the upper cover 30 side. The metal films 125A to 125D function as mass addition films that respectively make the mass per unit length (hereinafter, simply be referred to as the “mass”) of the tip-end parts 122A to 122D larger than the mass of the arm parts 123A to 123D. Thereby, the metal films 125A to 125D increase the amplitude while reducing the size of the vibration part 110. Moreover, the metal films 125A to 125D can be configured as a so-called frequency adjustment film that adjust a resonant frequency by scraping a part of the metal films 125A to 125D.

As further shown, the width of the tip-end part 122A is larger than the width of the arm part 123A. The same configuration holds for the tip-end parts 122B to 122D and the arm parts 123B to 123D. Thereby, even when the metal films 125A to 125D are omitted in an exemplary aspect, the weights of the tip-end parts 122A to 122D are still respectively larger than the weights of the arm parts 123A to 123D. However, the widths of the tip-end parts 122A to 122D can respectively be smaller than or equal to the widths of the arm parts 123A to 123D in alternative aspects.

As further shown, the shape of each of the tip-end parts 122A to 122D is a substantially rectangular shape having a curved shape with four rounded corners (for example, a so-called rounded shape). The shape of each of the arm parts 123A to 123D is a substantially rectangular shape having a rounded shape at near a root part connected to the base part 130, and near a connection part connected to each of the tip-end parts 122A to 122D. However, each of the tip-end parts 122A to 122D and the arm parts 123A to 123D is not limited to have the shape described above. For example, each of the tip-end parts 122A to 122D can have a trapezoid shape or an L-shape in alternative aspects. Moreover, each of the arm parts 123A to 123D can have a trapezoid shape, and a slit, a recess part, or a protrusion part can be formed at the arm parts 123A to 123D.

In the exemplary aspect, the shape and size of each of the vibration arms 121A to 121D is substantially the same. The length of each of the vibration arms 121A to 121D is, for example, about 450 μm. For example, the length of each of the arm parts 123A to 123D is about 300 μm, and the width thereof is about 50 μm. For example, the length of each of the tip-end parts 122A to 122D is about 150 μm, and the width thereof is about 70 μm.

The base part 130 includes a front-end part 131A, a back-end part 131B, a left-end part 131C, and a right-end part 131D. Each of the front-end part 131A, the back-end part 131B, the left-end part 131C, and the right-end part 131D is a part of an outer edge portion of the base part 130. The front-end part 131A is an end part extending in the X-axis direction at the vibration arms 121A to 121D side. The back-end part 131B is an end part extending in the X-axis direction at the side opposite to the vibration arms 121A to 121D. The left-end part 131C is an end part extending in the Y-axis direction at the vibration arm 121A side when seen from the vibration arm 121D. The right-end part 131D is an end part extending in the Y-axis direction at the vibration arm 121D side when seen from the vibration arm 121A. The vibration arms 121A to 121D are connected to the front-end part 131A.

a As further shown, the base part 130 has substantially rectangular shape in which the front-end part 131A and the back-end part 131B are the long sides and the left-end part 131C and the right-end part 131D are the short sides. Moreover, the imaginary plane P is defined along a perpendicular bisector of each of the front-end part 131A and the back-end part 131B. The base part 130 is not limited to that described above as long as it has a substantially plane-symmetrical structure with respect to the imaginary plane P, and for example, the base part 130 can have a trapezoid shape in which one of the front-end part 131A and the back-end part 131B is longer than the other. Moreover, at least one of the front-end part 131A, the back-end part 131B, the left-end part 131C, and the right-end part 131D can be bent or curved.

As one example, a base part length, which is the largest distance in the Y-axis direction between the front-end part 131A and the back-end part 131B, is about 35 μm. Moreover, as one example, a base part width, which is the largest distance in the X-axis direction between the left-end part 131C and the right-end part 131D, is about 265 μm. Note that, in the configuration example shown in FIG. 3, the base part length corresponds to the length of the left-end part 131C or the right-end part 131D, and the base part width corresponds to the width of the front-end part 131A or the back-end part 131B.

As illustrated in FIG. 3, the holding part or frame 140 includes a front frame 141A, a back frame 141B, a left frame 141C, and a right frame 141D. Each of the front frame 141A, the back frame 141B, the left frame 141C, and the right frame 141D is a part of the substantially rectangular frame body surrounding the vibration part 110. In an exemplary aspect, the front frame 141A is a portion extending in the X-axis direction at the excitation part 120 side when seen from the base part 130. The back frame 141B is a portion extending in the X-axis direction at the base part 130 side when seen from the excitation part 120. The left frame 141C is a portion extending in the Y-axis direction at the vibration arm 121A side when seen from the vibration arm 121D. The right frame 141D is a portion extending in the Y-axis direction at the vibration arm 121D side when seen from the vibration arm 121A. Each of the front frame 141A and the back frame 141B is bisected by the imaginary plane P.

Both ends of the left frame 141C are connected to the respective ones of one end of the front frame 141A and one end of the back frame 141B. Both ends of the right frame 141D are connected to the respective ones of the other end of the front frame 141A and the other end of the back frame 141B. The front frame 141A and the back frame 141B are opposed to one another in the Y-axis direction while sandwiching the vibration part 110 therebetween. The left frame 141C and the right frame 141D are opposed to one another in the X-axis direction while sandwiching the vibration part 110 therebetween.

The supporting arm 150 is provided on the inner side of the holding part 140 so as to connect the base part 130 and the holding part 140. In the configuration example shown in FIG. 3, the supporting arm 150 includes a left supporting arm 151A and a right supporting arm 151B when seen in plan view from the upper cover 30 side. The imaginary plane P is located between the right supporting arm 151B and the left supporting arm 151A, and the right supporting arm 151B and the left supporting arm 151A are plane-symmetry with one another.

The left supporting arm 151A connects the back-end part 131B of the base part 130 and the left frame 141C of the holding part 140. The right supporting arm 151B connects the back-end part 131B of the base part 130 and the right frame 141D of the holding part 140. The left supporting arm 151A includes a support back arm 152A and a support side arm 153A, and the right supporting arm 151B includes a support back arm 152B and a support side arm 153B.

The support back arms 152A and 152B extend from the back-end part 131B of the base part 130 between the back-end part 131B of the base part 130 and the holding part 140. In an exemplary aspect, the support back arm 152A extends from the back-end part 131B of the base part 130 toward the back frame 141B, and then is bent to extend toward the left frame 141C. The support back arm 152B extends from the back-end part 131B of the base part 130 toward the back frame 141B, and then is bent to extend toward the right frame 141D. The width of each of the support back arms 152A and 152B is smaller than the width of each of the vibration arms 121A to 121D.

The support side arm 153A extends along the outer vibration arm 121A between the outer vibration arm 121A and the holding part 140. The support side arm 153B extends along the outer vibration arm 121D between the outer vibration arm 121D and the holding part 140. In an exemplary aspect, the support side arm 153A extends from an end portion of the support back arm 152A at the left frame 141C side toward the front frame 141A, and then is bent to be connected to the left frame 141C. The support side arm 153B extends from an end portion of the support back arm 152B at the right frame 141D side toward the front frame 141A, and then is bent to be connected to the right frame 141D. The width of each of the support side arms 153A and 153B is substantially equal to the width of each of the support back arms 152A and 152B.

It is noted that the supporting arm 150 is not limited to have the configuration described above. For example, the supporting arm 150 can be connected to the left-end part 131C and the right-end part 131D of the base part 130. Moreover, the supporting arm 150 can be connected to the front frame 141A or the back frame 141B of the holding part 140. Moreover, the number of the supporting arms 150 can be one, or can be three or more in alternative aspects.

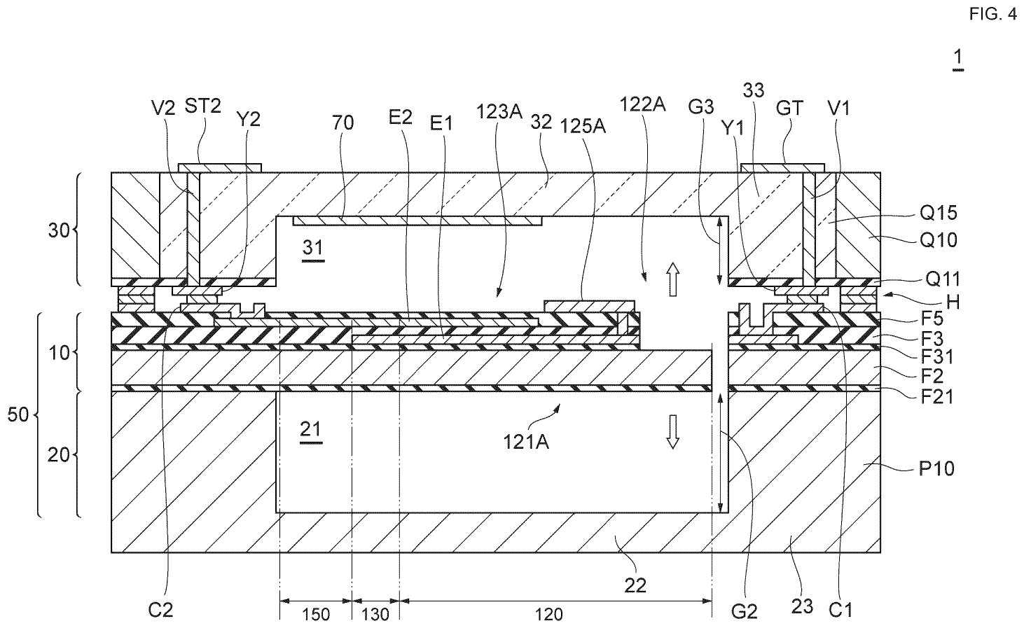

Next, a cross-sectional structure of the resonance device 1 according to the first exemplary embodiment is described with reference to FIG. 4. FIG. 4 is a sectional view of the resonance device according to the first exemplary embodiment. It is noted that FIG. 4 is a diagram for schematically explaining multilayer structure of the resonance device 1, and the component members illustrated in FIG. 4 are not necessarily positioned on a cross section in the same plane. For purposes of this disclosure, the direction from the lower cover 20 to the upper cover 30 is referred to as “up (upward)”, and the direction from the upper cover 30 to the lower cover 20 is referred to as “down (downward)”.

As further shown, the resonator 10 is held between the lower cover 20 and the upper cover 30. In an exemplary aspect, the holding part 140 of the resonator 10 is joined to each of the side wall 23 of the lower cover 20 and the side wall 33 of the upper cover 30. In this manner, the lower cover 20, the upper cover 30, and the holding part 140 form the vibration space where the vibration part 110 is vibratable. Each of the resonator 10, the lower cover 20, and the upper cover 30 is formed using a silicon (Si) substrate as one example. Note that each of the resonator 10, the lower cover 20, and the upper cover 30 can be formed using a silicon on insulator (SOI) substrate in which a silicon layer and a silicon oxide film are laminated on one another. Moreover, each of the resonator 10, the lower cover 20, and the upper cover 30 can be formed using a substrate other than the silicon substrate as long as processing using microfabrication technology is applicable to the substrate. Examples of the substrate other than the silicon substrate include a compound semiconductor substrate, a glass substrate, a ceramic substrate, a resin substrate, and combination thereof.

As illustrated in FIG. 4, the resonator 10 includes a silicon oxide film F21, a silicon substrate F2, an insulating film F31, the metal film El, a piezoelectric film F3, the metal film E2, and a protection film F5. The resonator 10 further includes, at the tip-end parts 122A to 122D, the metal films 125A to 125D. The vibration part 110, the holding part 140, and the supporting arm 150 are formed integrally through the same process. In an exemplary aspect, patterning through removal processing is performed with respect to a multilayer body including the silicon substrate F2, the insulating film F31, the metal film E1, the piezoelectric film F3, the metal film E2, the protection film F5, and the like, thereby forming the vibration part 110, the holding part 140, and the supporting arm 150. The removal processing is performed through, for example, dry-etching in which an argon (Ar) ion beam is radiated. The removal processing can be performed through other methods, such as wet-etching and laser-etching as would be appreciated to those skilled in the art.

However, in the tip-end parts 122A to 122D of the vibration arms 121A to 121D, materials that form the surfaces are different between a base-end-side portion located at the fixed-end side of the vibration arms 121A to 121D and a tip-end-side portion located at the open-end side of the vibration arms 121A to 121D. In an exemplary aspect, at the base-end-side portion of the tip-end parts 122A to 122D, the surface facing the bottom plate 32 of the upper cover 30 is provided by the metal films 125A to 125D. At the tip-end-side portion of the tip-end parts 122A to 122D, the surface facing the bottom plate 32 of the upper cover 30 is provided by the silicon substrate F2. That is, at the tip-end parts 122A to 122D, the insulating film F31, the metal film E1, the piezoelectric film F3, the metal film E2, the protection film F5, and the metal films 125A to 125D are provided to the base-end-side portion, but not to the tip-end-side portion.

The silicon oxide film F21 is provided to a lower surface of the silicon substrate F2 and is sandwiched between a silicon substrate P10 and the silicon substrate F2. The silicon oxide film F21 is made of a silicon oxide containing Si02 and the like, for example. A part of the silicon oxide film F21 is exposed to the cavity 21 of the lower cover 20. The silicon oxide film F21 is configured to function as a temperature characteristics correction layer that reduces a temperature coefficient of a resonant frequency of the resonator 10, that is, a change rate of the resonant frequency per unit temperature, at least at the vicinity of room temperature. Therefore, the silicon oxide film F21 improves the temperature characteristics of the resonator 10. Note that the silicon oxide film can be formed on the upper surface of the silicon substrate F2, or can be formed on both of the upper surface and the lower surface of the silicon substrate F2.

According to the exemplary aspect, the silicon substrate F2 is made of a single crystal of silicon. For example, the silicon substrate F2 is made of a degenerated n-type silicon (Si) semiconductor having the thickness of about 6 μm. The silicon substrate F2 can contain, as an n-type dopant, phosphorus (P), arsenic (As), antimony (Sb), or the like. A resistance value of degenerate silicon (Si) used for the silicon substrate F2 is, for example, less than 16 mΩ·cm, and more desirably 1.2 mΩ·cm or less.

Moreover, the insulating film F31 is provided between the silicon substrate F2 and the metal film E1. The insulating film F31 suppresses the occurrence of parasitic capacitance and occurrence of short-circuiting at an end portion of the resonance device 1. For example, the insulating film F31 is made of a piezoelectric material similar to the piezoelectric film F3. The material of the insulating film F31 is not limited to this, and can be, for example, a silicon oxide, a silicon nitride, or the like. It is noted that the insulating film F31 can be omitted in an alternative aspect.

The metal film E1 is stacked on the insulating film F31, the piezoelectric film F3 is stacked on the metal film E1, and the metal film E2 is stacked on the piezoelectric film F3. Each of the metal films El and E2 includes a portion that is configured to function as an excitation electrode that excites the vibration arms 121A to 121D, and a portion that is configured to function as an extended electrode that electrically connects the excitation electrode to an external power source. The portions functioning as the excitation electrode in the respective metal films E1 and E2 are opposed to one another while sandwiching the piezoelectric film F3 therebetween at the arm parts 123A to 123D of the vibration arms 121A to 121D. The portions functioning as the extended electrode in the metal films E1 and E2 are, for example, extended from the base part 130 to the holding part 140 via the supporting arm 150. The metal film E1 is electrically continuous across the entire resonator 10. The metal film E2 is electrically isolated between a portion formed at the outer vibration arms 121A and 121D and a portion formed at the inner vibration arms 121B and 121C. The metal film El corresponds to one example of the lower electrode, and the metal film E2 corresponds to one example of the upper electrode. Note that the insulating film F31 can be omitted, and in this case, the metal film El is provided on the silicon substrate F2.

The thickness of each of the metal films E1 and E2 is, for example, about 0.1 μm or more and 0.2 μm or less. The metal films E1 and E2 are film-formed and then patterned to be the excitation electrode, the extended electrode, and the like through removal processing such as etching. The metal films E1 and E2 are made of, for example, a metal material whose crystal structure is body-centered cubic. In an exemplary aspect, the metal films E1 and E2 are made of molybdenum (Mo), tungsten (W), or the like. In an exemplary case in which the silicon substrate F2 is a degenerate semiconductor substrate having high conductivity, the metal film E1 can be omitted, and the silicon substrate F2 can function as the lower electrode.

The piezoelectric film F3 is a thin film made of a piezoelectric material that performs conversion between electrical energy and mechanical energy. In operation, the piezoelectric film F3 extends and contracts in the Y-axis direction in the in-plane direction of the XY plane in accordance with an electric field applied between the metal film E1 and the metal film E2. This extension and contraction of the piezoelectric film F3 causes the vibration arms 121A to 121D to bend to have displacement at their open end toward the bottom plate 22 of the lower cover 20 and the bottom plate 32 of the upper cover 30. Alternating voltage with mutually opposite phases is applied to the upper electrode of the outer vibration arms 121A and 121D and the upper electrode of the inner vibration arms 121B and 121C. Therefore, the outer vibration arms 121A and 121D and the inner vibration arms 121B and 121C vibrate with the opposite phases. For example, when the open end of the outer vibration arms 121A and 121D has displacement toward the lower cover 20, the open end of the inner vibration arms 121B and 121C has displacement toward the upper cover 30. Such vibration with the opposite phases causes, in the vibration part 110, torsional moment centering on a rotational axis extending in the Y-axis direction. The base part 130 bends due to this torsional moment, and the left-end part 131C and the right-end part 131D have displacement toward the lower cover 20 or the upper cover 30. That is, the vibration part 110 of the resonator 10 vibrates in an out-of-plane bending vibration mode.

For example, the piezoelectric film F3 is made of a piezoelectric material having a crystal structure of a wurtzite-type hexagonal crystal structure. Examples of such a piezoelectric material include a nitride and an oxide, such as aluminum nitride (AN), scandium aluminum nitride (ScAlN), zinc oxide (ZnO), gallium nitride (GaN), and indium nitride (InN). Note that scandium aluminum nitride is obtained by part of aluminum in aluminum nitride being replaced by scandium. Similarly, a piezoelectric material in which part of aluminum in aluminum nitride is replaced by another element can be a piezoelectric material in which the part of aluminum is replaced by two elements of magnesium (Mg) and niobium (Nb) or two elements of magnesium (Mg) and zirconium (Zr). For example, the thickness of the piezoelectric film F3 is about 1 μm, but can be about 0.2 μm to 2 μm.

The protection film F5 is stacked on the metal film E2. The protection film F5 protects the metal film E2 from oxidation, for example. A material of the protection film F5 is, for example, an oxide, a nitride, or an oxynitride, including aluminum (Al), silicon (Si), or tantalum (Ta). A parasitic capacitance reduction film that reduces parasitic capacitance formed between internal wires of the resonator 10 can be stacked on the protection film F5.

The metal films 125A to 125D are stacked on the protection film F5 at the tip-end parts 122A to 122D. The metal films 125A to 125D can be configured to function as the frequency adjustment film as well as functioning as the mass addition film. From the viewpoint as the frequency adjustment film, the metal films 125A to 125D are desirably made of a material whose mass reduction rate by etching is higher than that of the protection film F5. The mass reduction rate is represented by a product of an etching rate and a density. The etching rate is a thickness to be removed per unit time. A magnitude relation regarding the etching rate between the protection film F5 and the metal films 125A to 125D is arbitrary as long as the relation regarding the mass reduction rate is as described above. Moreover, from the viewpoint as the mass addition film, the metal films 125A to 125D are desirably made of a material with large specific gravity. From the above two viewpoints, the material of the metal films 125A to 125D is, for example, a metal material, such as molybdenum (Mo), tungsten (W), gold (Au), platinum (Pt), nickel (Ni), and titanium (Ti). It is noted that when the metal films 125A to 125D are configured as the frequency adjustment film, a part of the protection film F5 can be removed together in trimming processing of the metal films 125A to 125D. In such a case, the protection film F5 also corresponds to the frequency adjustment film.

A part of each of the metal films 125A to 125D is removed through trimming processing in a frequency adjustment process. The trimming processing of the metal films 125A to 125D is dry-etching in which, for example, an argon (Ar) ion beam is radiated. The ion beam is excellent at processing efficiency because it can irradiate a wide range, whereas it can charge the metal films 125A to 125D. The metal films 125A to 125D are desirably grounded in order to prevent coulombic interaction due to charging of the metal films 125A to 125D from changing a vibration track of the vibration arms 121A to 121D to deteriorate the vibration characteristics of the resonator 10. Therefore, the metal film 125A is electrically connected to the metal film E1 by a through-electrode penetrating the piezoelectric film F3 and the protection film F5. Similarly, the metal films 125B to 125D (not illustrated) are also electrically connected to the metal film El by through-electrodes. Note that the metal films 125A to 125D can be electrically connected to the metal film E1 by side-surface electrodes provided to side surfaces of the tip-end parts 122A to 122D, for example. The metal films 125A to 125D can be electrically connected to the metal film E2.

Extended wires C1 and C2 are formed on the protection film F5 of the holding part 140. The extended wire C1 is electrically connected to the metal film E1 through a through-hole formed in the piezoelectric film F3 and the protection film F5. The extended wire C2 is electrically connected to the metal film E2 of the outer vibration arms 121A and 121D through a through-hole formed in the protection film F5. Although not illustrated, an extended wire electrically connected to the metal film E2 of the inner vibration arms 121B and 121C is also formed on the protection film F5. The extended wires C1 and C2 are made of a metal material, such as aluminum (Al), germanium (Ge), gold (Au), and tin (Sn).

The bottom plate 22 and the side wall 23 of the lower cover 20 are integrally formed by the silicon substrate P10. According to the exemplary aspect, the silicon substrate P10 is made of an undegenerated silicon semiconductor and has resistivity of, for example, 10 Ω·cm or more. Moreover, the thickness of the lower cover 20 is larger than the thickness of the silicon substrate F2, and is, for example, about 150 μm.

Assuming that the resonator 10 and the lower cover 20 form the MEMS substrate 50 in an exemplary aspect, for example, the silicon substrate P10 of the lower cover 20 corresponds to a support substrate (handle layer) of an SOI substrate, the silicon oxide film F21 of the resonator 10 corresponds to a BOX layer of the SOI substrate, and the silicon substrate F2 of the resonator 10 corresponds to an active layer (device layer) of the SOI substrate.

The bottom plate 32 of the upper cover 30 is formed by a glass substrate Q15, and the side wall 33 of the upper cover 30 is formed by a silicon substrate Q10 and the glass substrate Q15. The silicon substrate Q10 is made of an undegenerated silicon semiconductor, and has resistivity of, for example, 10 Ω·cm or more. The glass substrate Q15 is made of glass having a silicon oxide (for example, SiO₂) as a main component. Here, the main component of the glass refers to a component that forms 50 mass % or more of the entire components that form the glass. As one example, the glass substrate Q15 is made of silicate glass whose main component is SiO₂. A portion surrounding through-electrodes V1 and V2 described later and a portion in contact with the outer terminal are formed by the glass substrate Q15. A silicon oxide film Q11 is provided to a lower surface of the side wall 33. The silicon oxide film Q11 electrically isolates inner terminals Y1 and Y2 described later from the silicon substrate Q10. The silicon oxide film Q11 is formed, for example, by chemical vapor deposition (CVD). The thickness of the upper cover 30 is, for example, about 150 μm.

It is noted that when the inner terminals Y1 and Y2 are provided on the outer side of the silicon substrate Q10 when seen in plan view in the thickness direction, the silicon oxide film Q11 can be omitted. When the inner terminals Y1 and Y2 are provided on the outer side of the silicon substrate Q10, the silicon oxide film Q11 can be provided only to a region of the side wall 33 formed by the silicon substrate Q10, and can be omitted at a region formed by the glass substrate Q15.

The upper cover 30 includes a metal film 70, the through-electrodes V1 and V2, the inner terminals Y1 and Y2, the ground terminal GT, and the power terminal ST2.

The metal film 70 is provided to a lower surface of the bottom plate 32 of the upper cover 30. The metal film 70 is a getter that occludes gas in the vibration space formed by the cavity 21 of the lower cover 20 and the cavity 31 of the upper cover 30 to improve degree of vacuum, and, for example, occludes hydrogen gas, outgas, and the like. The metal film 70 includes, for example, titanium (Ti), zirconium (Zr), vanadium (V), niobium (Nb), tantalum (Ta), or an alloy containing at least one of them. The metal film 70 can include an oxide of alkali metal or an oxide of alkaline-earth metal. Between the silicon substrate Q10 and the metal film 70, for example, a layer (not illustrate), such as a layer that prevents diffusion of hydrogen from the silicon substrate Q10 to the metal film 70, and a layer that improves close contact between the silicon substrate Q10 and the metal film 70, can be provided.

The metal film 70 is configured to avoid a region facing the tip-end-side portion of the tip-end parts 122A to 122D in the thickness direction. That is, a region of the bottom plate 32 of the upper cover 30, the region facing the tip-end-side portion of the tip-end parts 122A to 122D, has the bottom surface that is provided by the silicon substrate Q10.

The through-electrodes V1 and V2 are provided to the side wall 33 of the upper cover 30. The through-electrodes V1 and V2 are provided inside through-holes penetrating the side wall 33 in the Z-axis direction. The through-electrodes V1 and V2 are surrounded by the glass substrate Q15, thereby being insulated from one another. The through-electrodes V1 and V2 are, for example, formed by polycrystalline silicon (Poly-Si), copper (Cu), gold (Au), or the like being filled into the through-holes.

The inner terminals Y1 and Y2 are provided to the lower surface of the side wall 33 of the upper cover 30. The inner terminal Y1 is electrically connected to the ground terminal GT by the through-electrode V1. The inner terminal Y2 is electrically connected to the power terminal ST2 by the through-electrode V2. The inner terminals Y1 and Y2 are electrically insulated from one another by the glass substrate Q15 and the silicon oxide film Q11. The inner terminal Y1 is a connection terminal that electrically connects the through-electrode V1 and the extended wire C1. The inner terminal Y2 is a connection terminal that electrically connects the through-electrode V2 and the extended wire C2. For example, the inner terminals Y1 and Y2 are formed by application of plating of nickel (Ni), gold (Au), silver (Ag), copper (Cu), or the like to a metallization layer (underlying layer), such as chromium (Cr), tungsten (W), nickel (Ni), or the like.

The ground terminal GT and the power terminal ST2 are provided to the upper surface of the side wall 33 of the upper cover 30. The ground terminal GT and the power terminal ST2 are electrically insulated from one another by the glass substrate Q15. For example, the ground terminal GT and the power terminal ST2 are formed by application of plating of nickel (Ni), gold (Au), silver (Ag), copper (Cu), or the like to a metallization layer (underlying layer), such as chromium (Cr), tungsten (W), nickel (Ni), or the like.

Note that, although not illustrated, an inner terminal that electrically connects the metal film E2 of the inner vibration arms 121B and 121C and the power terminal ST1 is further provided to the side wall 33 of the upper cover 30. Moreover, a through-electrode (not illustrated) that electrically connects the above-described inner terminal (not illustrated) and the power terminal ST1 is further provided to the side wall 33 of the upper cover 30.

A joint part H is formed between the side wall 33 of the upper cover 30 and the holding part 140 of the resonator 10. The joint part H is formed to have a frame shape that continues in a circumferential direction in such a manner as to surround the vibration part 110 when seen in plan view. The joint part H hermetically seals the vibration space formed by the cavities 21 and 31 in the vacuum state. For example, the joint part H is formed by a metal film in which an aluminum (Al) film, a germanium (Ge) film, and an aluminum (Al) film are stacked in this order from the resonator 10 side to be eutectic bonded with one another. The joint part H can include gold (Au), tin (Sn), copper (Cu), titanium (Ti), aluminum (Al), germanium (Ge), silicon (Si), and an alloy including at least one type of them. Moreover, the joint part H can include an insulating material including a metal compound, such as titanium nitride (TiN) and tantalum nitride (TaN), so as to improve close contact between the resonator 10 and the upper cover 30. Note that although each metal film of the joint part H is illustrated as an independent film, in practice, it forms a eutectic alloy, and thereby a clear border does not necessarily exist.

Note that the material of the joint part H is not limited to the metal described above and is suitably selected depending on required sealing performance. For example, the joint part H can be provided by an organic polymer-based adhesive or an inorganic glass-based adhesion.

At the tip-end-side portion of the tip-end parts 122A to 122D of the vibration arms 121A to 121D, there are a gap G2 between the vibration arms 121A to 121D and the lower cover 20, and a gap G3 between the vibration arms 121A to 121D and the upper cover 30. The gap G2 is a distance between the tip-end-side portion of the tip-end parts 122A to 122D of the vibration arms 121A to 121D and the bottom plate 22 of the lower cover 20 in the thickness direction in the non-vibration state. The gap G2 corresponds to a distance between the silicon oxide film F21 and the silicon substrate P10 of the bottom plate 22 in the Z-axis direction. The gap G3 is a distance between the tip-end-side portion of the tip-end parts 122A to 122D of the vibration arms 121A to 121D and the bottom plate 32 of the upper cover 30 in the thickness direction in the non-vibration state. The gap G3 corresponds to a distance between the silicon oxide film Q11 and the glass substrate Q15 of the bottom plate 32 in the Z-axis direction.

The gap G3 at the upper cover 30 side is smaller than the gap G2 at the lower cover 20 side. Therefore, when the amplitude of the vibration arms 121A to 121D increases, the vibration arms 121A to 121D contact the upper cover 30 before contacting the lower cover 20. That is, the maximum amplitude of the vibration arms 121A to 121D is limited by the gap G3 at the upper cover 30 side.

Fracture stress (7.8 GPa) of SiOz, which is the main component of the glass substrate Q15 of the upper cover 30, is higher than fracture stress (4.4 GPa) of Si, which is the main component of the silicon substrate F2 of the vibration arms 121A to 121D. Therefore, in a case of collision between the vibration arms 121A to 121D and the upper cover 30 at a low speed, when the external stress that acts on the glass substrate Q15 particularly at the time of collision is less than 7.8 GPa, Si of the silicon substrate F2 is more likely to get fractured than SiOz of the glass substrate Q15. Therefore, in order to suppress the generation of fine particles from the glass substrate Q15 attributed to collision between the vibration arms 121A to 121D and the upper cover 30, the speed of collision between the vibration arms 121A to 121D and the upper cover 30 is desirably low. Therefore, the size of the gap G3 at the upper cover 30 side is, for example, desirably 12% or less, further desirably 11% or less, and still further desirably 10% or less of the length of the vibration arms 121A to 121D. In order to avoid contact of the vibration arms 121A to 121D with the upper cover 30 at the time of normal operation of the resonance device 1, the size of the gap G3 at the upper cover 30 side is, for example, desirably 5% or more, further desirably 6% or more, and still further desirably 7% or more of the length of the vibration arms 121A to 121D.

Note that, at the time of collision between the vibration arms 121A to 121D and the upper cover 30, the external stress that acts on the vibration arms 121A to 121D is larger than the external stress that acts on the upper cover 30. Therefore, even when the speed of collision between the vibration arms 121A to 121D and the upper cover 30 is low, the external stress sufficient to scrape off Si acts on the silicon substrate F2 at the time of collision.

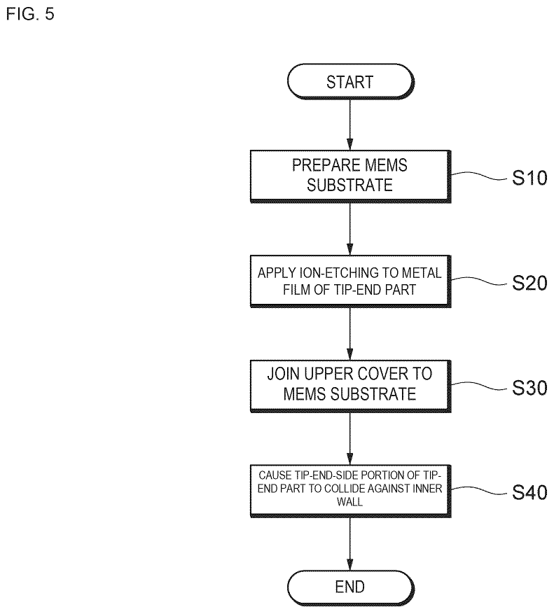

Next, a method for manufacturing the resonance device 1 according to the first exemplary embodiment is described with reference to FIG. 5. FIG. 5 is a flowchart illustrating a method for manufacturing the resonance device according to the first exemplary embodiment.

First, the MEMS substrate 50 is prepared (S10).

In an exemplary aspect, first, the silicon substrates P10 and F2, each of which is one-surface mirror polished, are prepared. The cavity 21 is formed at the mirror-surface side of the silicon substrate P10, and the silicon oxide film F21 is formed at the mirror-surface side of the silicon substrate F2. Next, the mirror-surface side of the silicon substrate P10 and the mirror-surface side of the silicon substrate F2 are brought in contact with one another and heat-treated, so that the silicon substrate P10 and the silicon oxide film F21 are directly joined one another. Next, the insulating film F31, the metal film E1, the piezoelectric film F3, the metal film E2, the protection film F5, and the metal films 125A to 125D are stacked in this order on the silicon substrate F2 to provide a multilayer body that forms the resonator 10. Next, the multilayer body receives removal processing by argon-ion-etching to form the vibration part 110, the holding part 140, and the supporting arm 150.

Note that after the vibration part 110, the holding part 140, and the supporting arm 150 are formed, the silicon substrate P10 and the silicon oxide film F21 can be directly joined one another.

Next, ion-etching is applied to the metal films 125A to 125D of the tip-end parts 122A to 122D (S20).

In an exemplary aspect, trimming processing is applied to the metal films 125A to 125D through ion milling, and the resonant frequency of the resonator 10 is adjusted by a change in mass of the vibration arms 121A to 121D. At this time, a surface of the protection film F5 can be trimmed together. Step S20 corresponds to one example of a frequency adjustment process before sealing.

Next, the upper cover 30 is joined to the MEMS substrate 50 (S30).

In an exemplary aspect, the lower surface of the upper cover 30 and the upper surface of the MEMS substrate 50 are eutectic bonded by the joint part H. First, the upper cover 30 and the MEMS substrate 50 are positioned in such a manner that the inner terminals Y1 and Y2 are respectively in contact with the extended wires C1 and C2. After the positioning, the upper cover 30 and the MEMS substrate 50 sandwich the joint part H, and heat treatment is performed at the temperature of the eutectic point or more. The temperature for the heat treatment is, for example, 424°0 C. or more, and a heating time period for the heat treatment is, for example, about 10 minutes or more and 20 minutes or less. At the time of heating, the upper cover 30 and the MEMS substrate 50 are pressed at the pressure of, for example, about 5 MPa or more and 25 MPa or less.

Next, the tip-end parts 122A to 122D of the vibration arms 121A to 121D are forced to collide against an inner wall (S40).

In an exemplary aspect, the silicon substrate F2 that forms the upper surface of the tip-end-side portion of the tip-end parts 122A to 122D is forced to collide against the glass substrate Q15 that forms the lower surface of the bottom plate 32 of the upper cover 30. First, voltage that is stronger than an electric field to be applied at the time of normal operation as the resonance device 1 is applied to the resonator 10 to cause the resonator 10 to vibrate at an amplitude larger than that at the time of normal operation (hereinafter, be referred to as “overexcitation”). The overexcited tip-end-side portion of the tip-end parts 122A to 122D of the vibration arms 121A to 121D collides against the bottom plate 32 of the upper cover 30. At the tip-end parts 122A to 122D, since their tip-end-side portion first collides against the bottom plate 32, the base-end-side portion does not contact the bottom plate 32. The Step S40 corresponds to one example of a frequency adjustment process after sealing.

As described above, in the tip-end-side portion of the tip-end parts 122A to 122D of the vibration arms 121A to 121D, the surface facing the bottom plate 32 of the upper cover 30 in the thickness direction is provided by the silicon substrate F2.

In this way, when the vibration arms 121A to 121D and the upper cover 30 are forced to collide against one another to adjust the resonant frequency after sealing, the metal films 125A to 125D do not contact the bottom plate 32 whereas the silicon substrate F2 contacts the bottom plate 32. Since an impact caused by the collision between the vibration arms 121A to 121D and the upper cover 30 is not absorbed by the metal films 125A to 125D, the metal films 125A to 125D do not impede the frequency adjustment process. Therefore, it is unnecessary to increase the gap G3 to avoid collision between the vibration arms 121A to 121D and the upper cover 30. For example, making the gap G3 smaller than the gap G2 can reduce the height of the upper cover 30.

The surface of the bottom plate 32 facing the tip-end parts 122A to 122D is provided by the glass substrate Q15 whose main component is a silicon oxide.

In this way, the glass substrate Q15 has fracture stress larger than that of the silicon substrate F2. Therefore, when the glass substrate Q15 and the silicon substrate F2 collide against one another, the silicon substrate F2 can be scraped while scraping of the glass substrate Q15 is suppressed. Thereby, generation of fine particles from the upper cover 30 can also be suppressed in the frequency adjustment process, and the total amount of fine particles generated in the vibration space can be reduced. Moreover, since the glass substrate Q15 has translucency, the resonator 10 is observable from outside. Thereby, malfunction which occurs inside the resonance device 1 after sealing is detectable through visual inspection.

The through-electrodes V1 and V2 are surrounded by the glass substrate Q15 whose main component is a silicon oxide.

In this way, the glass substrate Q15 having electrostatic capacity smaller than that of the silicon oxide film Q11 surrounds the through-electrodes V1 and V2. Therefore, parasitic capacitance that occurs at the through-electrodes V1 and V2 can be reduced.

Other exemplary embodiments are described below. Note that configurations which are the same as or similar to the configurations described in the first exemplary embodiment are denoted by the same or similar reference characters to suitably omit description thereof. Similar operation and effects attributed to similar configurations are not mentioned one by one.

### Second Exemplary Embodiment

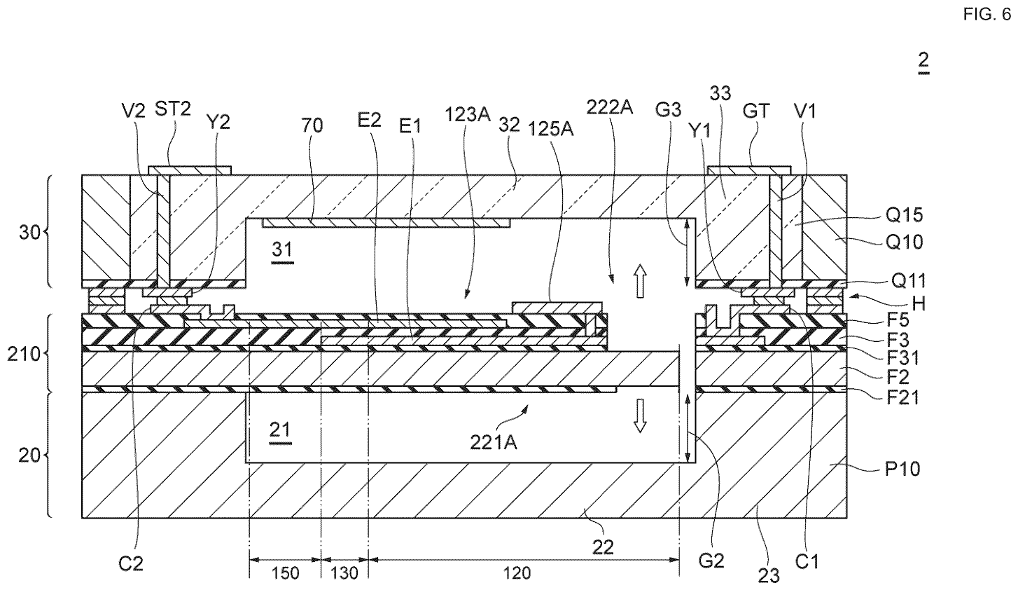

Next, a structure of a resonance device 2 according to a second exemplary embodiment is described with reference to FIG. 6. FIG. 6 is a sectional view of the resonance device according to the second exemplary embodiment.

At a tip-end-side portion of a tip-end part 222A of a vibration arm 221A, a surface facing the bottom plate 22 of the lower cover 20 is provided by the silicon substrate F2. That is, at the tip-end part 222A, the silicon oxide film F21 is provided to a base-end-side portion but not to the tip- end-side portion.

In this way, in the frequency adjustment process after sealing, the silicon substrate F2 that is more likely to be scraped than the silicon oxide film F21 can be forced to collide against the silicon substrate P10. Therefore, the frequency adjustment process after sealing can have improved efficiency. Moreover, fine particles generated from the tip-end part 222A can be dispersed to both of the lower cover 20 and the upper cover 30. The dispersed fine particles are small enough to get strong effect of van der Waals force, and thereby the fine particles attached to the lower cover, the upper cover, or the resonator is less likely to fall off. Therefore, frequency fluctuation that is attributed to falling and attaching of the fine particles is less likely to occur. However, an increase in density of the fine particles can cause the fine particle to form an aggregation. Influence of van der Waals force on the aggregation is smaller than that on the fine particles, and thereby the aggregation is more likely to fall off than the fine particles. When the tip-end part 222A of the vibration arm 221A is forced to collide against both of the lower cover 20 and the upper cover 30 in the frequency adjustment process after sealing, fine particles are generated at both of the lower cover 20 side and the upper cover 30 side. Therefore, as compared to a configuration in which fine particles are generated only at the upper cover 30 side, the density of the fine particles can be reduced. As a result, as compared to the configuration in which fine particles are generated only at the upper cover 30 side, occurrence of an aggregation is suppressed, and frequency fluctuation that is attributed to falling and attaching of the aggregation from and to a resonator 210 is also suppressed.

The gap G2 at the lower cover 20 side has substantially the same size as that of the gap G3 at the upper cover 30 side.

In this way, the density of the fine particles can further be reduced.

### Third Exemplary Embodiment

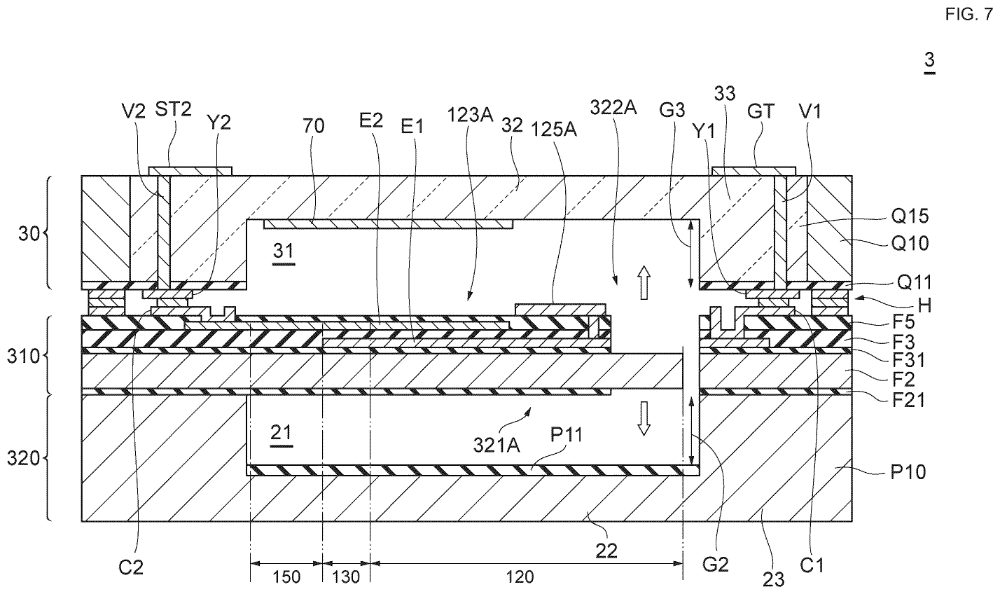

Next, a structure of a resonance device 3 according to a third exemplary embodiment is described with reference to FIG. 7. FIG. 7 is a sectional view of the resonance device according to the third exemplary embodiment.

At a tip-end-side portion of a tip-end part 322A of a vibration arm 321A, a surface facing the bottom plate 22 of a lower cover 320 is provided by the silicon substrate F2. A surface of the bottom plate 22 of the lower cover 320 facing the tip-end part 322A is provided by a silicon oxide film P11. The silicon oxide film P11 is provided on top of the silicon substrate P10.

In this way, in the frequency adjustment process after sealing, the silicon substrate F2 can be forced to collide against the silicon oxide film P11 that is less likely to be scraped than the silicon substrate P10. Therefore, generation of fine particles from the lower cover 320 is suppressed.

It is noted that the bottom plate of the lower cover can be provided by a glass substrate whose main component is a silicon oxide. In this case, since the bottom plate of the lower cover has translucency, the resonator is observable from outside at the lower-cover side. Thereby, malfunction which occurs inside the resonance device after sealing is detectable through visual inspection.

### Fourth Exemplary Embodiment

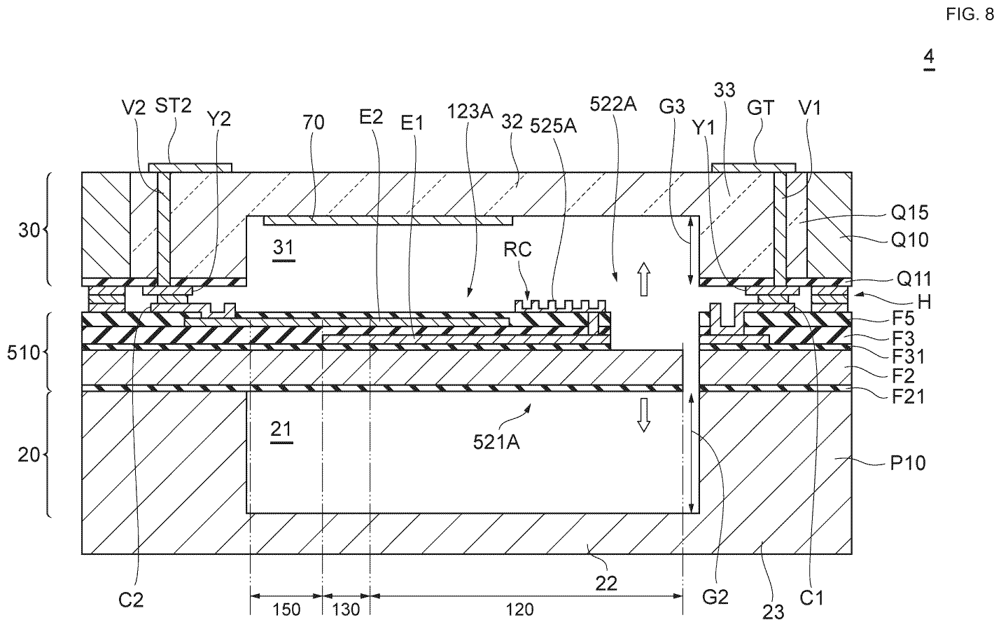

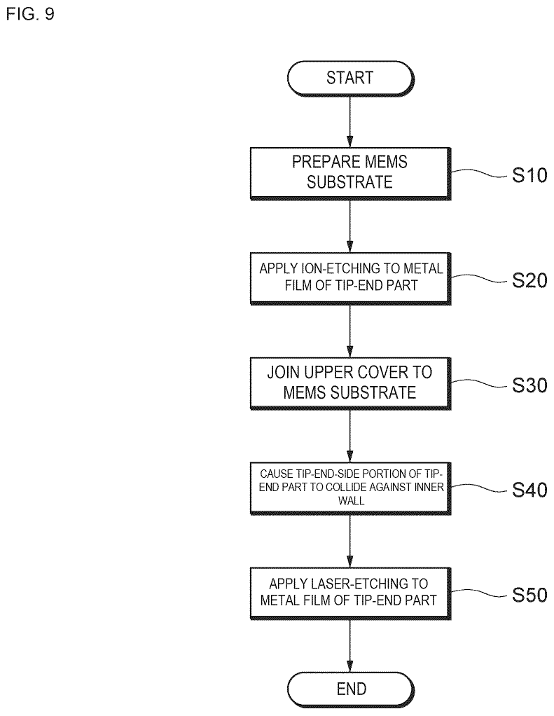

Next, a structure of a resonance device 4 and a method for manufacturing the resonance device 4 according to a fourth exemplary embodiment are described with reference to FIGS. 8 and 9. FIG. 8 is a sectional view of the resonance device according to the fourth exemplary embodiment. FIG. 9 is a flowchart illustrating the method for manufacturing the resonance device according to the fourth exemplary embodiment.

As illustrated in FIG. 8, a recess part RC is formed in a metal film 525A provided to a tip-end part 522A of a vibration arm 521A. The recess part RC is a bottomed groove part that opens to the bottom plate 32 side of the upper cover 30.

As illustrated in FIG. 9, the method for manufacturing the resonance device 4 further includes Step S50 in which laser-etching is applied to the metal film 525A of the tip-end part 522A after Step S40.

In an exemplary aspect, trimming processing is applied to the metal film 525A through laser ablation, and a resonant frequency of a resonator 510 is adjusted by a change in mass of the vibration arm 521A. Laser is radiated from outside through the glass substrate Q15 that forms the bottom plate 32 of the upper cover 30. The recess part RC corresponds to a process mark of removal processing by such laser ablation. The Step S50 corresponds to one example of a frequency adjustment process after sealing.

In this way, the resonant frequency after sealing can be adjusted by the two steps: Step $40 in which the resonant frequency is adjusted by overexcitation and Step S50 in which the resonant frequency is adjusted by laser ablation. Therefore, fine particles caused by collision between the vibration arm 521A against the lower cover 20 or the upper cover 30 at Step S40 can be reduced. As a result, frequency fluctuation that is attributed to the fine particles is suppressed.

It is noted that Step S50 can be performed before Step S40. Moreover, other than the metal film 525A, the protection film F5 or the like can receive removal processing through laser ablation at Step S50. Instead of the recess part RC, a through-hole can be formed in the metal film 525A. That is, a part of the metal film 525A can be removed entirely in the thickness direction by the removal processing through the laser ablation at Step S50.

A part or the whole of the exemplary embodiments of the present disclosure are appended below. Note that the present disclosure is not limited to the following additional notes.
<1>A resonance device including: a resonator including a vibration part, a holding part disposed at at least a part of a circumference of the vibration part, and a supporting arm connecting the vibration part and the holding part; and a first substrate including a first bottom plate configured to have a gap with respect to the vibration part in a thickness direction, and a first side wall extending from a circumferential edge part of the first bottom plate toward the holding part, in which the vibration part includes a vibration arm configured to perform out-of-plane bending vibration, and a tip-end part of the vibration arm includes a base-end-side portion and a tip-end-side portion, the base-end-side portion having a surface facing the first bottom plate and provided by a metal film, the tip-end-side portion being located closer to an open-end side than the base-end-side portion and having a surface facing the first bottom plate and made of silicon.
<2> The resonance device according to <1>, in which a surface of the first bottom plate is made of a silicon oxide, the surface facing the tip-end part.
<3> The resonance device according to <1> or <2>, in which the first bottom plate is made of glass including a silicon oxide as a main component.
21 4> The resonance device according to any one of <1> to <5>, in which the first substrate includes an inner terminal electrically connected to the resonator, an outer terminal electrically connected to an external substrate, and a through-electrode electrically connecting the inner terminal and the outer terminal, and a portion surrounding a circumference of the through-electrode is made of glass including a silicon oxide as a main component.
<5> The resonance device according to any one of <1> to <4>, further including: a second substrate including a second bottom plate configured to have a gap with respect to the vibration part in the thickness direction, and a second side wall extending from a circumferential edge part of the second bottom plate toward the holding part, in which a surface of the tip-end-side portion is made of silicon, the surface facing the second bottom plate.
<6> The resonance device according to <5>, in which a surface of the second bottom plate is made of a silicon oxide, the surface facing the tip-end part.
<7> device according to <5> or <6>, in which the second bottom plate is made of glass including a silicon oxide as a main component.

<8> The resonance device according to any one of <5> to <7>, in which a gap between the tip-end-side portion and the first bottom plate in the thickness direction is smaller than a gap between the tip-end-side portion and the second bottom plate in the thickness direction.
<9> The resonance device according to any one of <5> to <7>, in which a gap between the tip-end-side portion and the first bottom plate in the thickness direction is substantially equal to a gap between the tip-end-side portion and the second bottom plate in the thickness direction.
<10> The resonance device according to any one of <1> to <9>, in which a recess part is formed in the metal film at a side facing the first bottom plate.
<11> A method for manufacturing a resonance device, the resonance device including: a resonator including a vibration part, a holding part disposed at at least a part of a circumference of the vibration part, and a supporting arm connecting the vibration part and the holding part; and a first substrate including a first bottom plate configured to have a gap with respect to the vibration part in a thickness direction, and a first side wall extending from a circumferential edge part of the first bottom plate toward the holding part, in which the vibration part includes a vibration arm configured to perform out-of-plane bending vibration, and a tip-end part of the vibration arm includes a base-end-side portion and a tip-end-side portion, the base-end-side portion having a surface facing the first bottom plate and provided by a metal film, the tip-end-side portion being located closer to an open-end side than the base-end-side portion and having a surface facing the first bottom plate and made of silicon, the method including: preparing the resonator; preparing the first substrate; joining the resonator to the first substrate; and adjusting a frequency of the resonator by exciting the resonator to cause the tip-end-side portion to contact the first bottom plate.
<12> The method for manufacturing the resonance device according to <11>, in which a surface of the first bottom plate is made of a silicon oxide, the surface facing the tip-end part.
<13> The method for manufacturing the resonance device according to <11> or <12>, in which the first bottom plate is made of glass including a silicon oxide as a main component.
<14> The method for manufacturing the resonance device according to any one of <11> to <13>, the method further including: adjusting a frequency of the resonator by radiating a laser to the metal film from outside through the first bottom plate.
<15> The method for manufacturing the resonance device according to any one of <11> to <14>, the resonance device further including: a second substrate including a second bottom plate configured to have a gap with respect to the vibration part in the thickness direction, and a second side wall extending from a circumferential edge part of the second bottom plate toward the holding part, in which a surface of the tip-end-side portion is made of silicon, the surface facing the second bottom plate, and the adjusting the frequency of the resonator includes exciting the resonator to cause the tip-end-side portion to contact the second bottom plate.
<16> The method for manufacturing the resonance device according to <15>, in which a surface of the second bottom plate is made of a silicon oxide, the surface facing the tip-end part.

The exemplary embodiments according to the present disclosure are suitably applicable without particular limitation as long as they are applied to a device that utilizes frequency characteristics of a vibrator, such as a timing device, a sound emitter, an oscillator, a load sensor, and the like.

As described above, according to one exemplary aspect of the present disclosure, a resonance device having a reduced size and a method for manufacturing the resonance device can be provided.

Note that the exemplary embodiments described above are intended to facilitate understanding of the present disclosure and are not intended to be construed as limiting the present disclosure. The present disclosure can be changed/modified without departing from the spirit of the present disclosure, and equivalents thereof are also included in the present disclosure. That is, those in which design changes are appropriately made to each exemplary embodiment by those skilled in the art are also included in the scope of the present disclosure as long as they have the features of the present disclosure. For example, the elements included in each exemplary embodiment and arrangements, materials, conditions, shapes, sizes, and the like thereof are not limited to those exemplified and can be appropriately changed. Further, the elements included in each exemplary embodiment can be combined as much as technically possible, and combinations of these are also included in the scope of the present disclosure as long as they include the features of the present disclosure.

### REFERENCE SIGNS LIST

1 resonance device
10 resonator
20 lower cover
30 upper cover
21, 31 cavity
22, 32 bottom plate
23, 33 side wall
50 MEMS substrate
70 metal film
110 vibration part
120 excitation part
121A to 121D vibration arm
122A to 122D tip-end part
125A to 125D metal film
130 base part
140 holding part
150 supporting arm

What is claimed is:

1. A resonance device comprising:
a resonator including:
a vibration part,
a frame disposed at at least a portion of a circumference of the vibration part, and
a supporting arm configured to connect the vibration part to the frame;
a first substrate including:
a first bottom plate configured to have a first gap to the vibration part in a thickness direction, and a first side wall extending from a circumferential edge of the first bottom plate toward the frame;
wherein:
the vibration part includes a vibration arm configured to perform an out-of-plane bending vibration, and
the vibration arm includes a tip-end with a base-end-side portion and a tip-end-side portion that is closer to an open-end side of the vibration arm than the base-end-side portion, the base-end-side portion having a first surface that includes a metal film facing the first bottom plate, the tip-end-side portion having a second surface that includes silicon facing the first bottom plate.

2. The resonance device according to claim 1, wherein the first bottom plate includes a surface that includes a silicon oxide and that faces the tip-end.

3. The resonance device according to claim 1, wherein the first bottom plate comprises a glass including a silicon oxide as a main component.

4. The resonance device according to claim 1, wherein the first substrate includes:
an inner terminal configured to be electrically connected to the resonator;
an outer terminal configured to be electrically connected to an external substrate;
a through-electrode configured to electrically connect the inner terminal to the outer terminal; and
wherein a portion surrounding a circumference of the through-electrode comprises a glass including a silicon oxide as a main component.

5. The resonance device according to claim 1, further comprising a second substrate including:
a second bottom plate configured to have a second gap to the vibration part in the thickness direction, and
a second side wall extending from a circumferential edge of the second bottom plate toward the frame,
wherein the tip-end-side portion includes a third surface that includes silicon and that faces the second bottom plate.

6. The resonance device according to claim 5, wherein the second bottom plate includes a fourth surface that includes a silicon oxide, the fourth surface facing the tip-end.

7. The resonance device according to claim 5, wherein the second bottom plate comprises a glass including a silicon oxide as a main component.

8. The resonance device according to claim 5, wherein a first gap thickness between the tip-end-side portion and the first bottom plate in the thickness direction is smaller than a second gap thickness between the tip-end-side portion and the second bottom plate in the thickness direction.

9. The resonance device according to claim 5, wherein a first gap thickness between the tip-end-side portion and the first bottom plate in the thickness direction is substantially equal to a second gap thickness between the tip-end-side portion and the second bottom plate in the thickness direction.

10. The resonance device according to claim 1, wherein the metal film of the first surface includes a recess facing the first bottom plate.

11. A method for manufacturing a resonance device, the resonance device including a resonator that includes:
a vibration part,
a frame disposed at at least a portion of a circumference of the vibration part, and
a supporting arm configured to connect the vibration part to the frame;
a first substrate including:
a first bottom plate configured to have a first gap to the vibration part in a thickness direction, and
a first side wall extending from a circumferential edge of the first bottom plate toward the frame, in which:
the vibration part includes a vibration arm configured to perform an out-of-plane bending vibration, and
the vibration arm includes a tip-end with a base-end-side portion and a tip-end-side portion that is closer to an open-end side of the vibration arm than the base-end-side portion, the base-end-side portion having a first surface that includes a metal film facing the first bottom plate, the tip-end-side portion having a second surface that includes silicon facing the first bottom plate,
the method comprising:
preparing the resonator;
preparing the first substrate;
joining the resonator to the first substrate; and
adjusting a frequency of the resonator by exciting the resonator to cause the tip-end-side portion to contact the first bottom plate.

12. The method according to claim 11, wherein the first bottom plate includes a surface that includes a silicon oxide and that faces the tip-end.

13. The method according to claim 11, wherein the first bottom plate comprises a glass including a silicon oxide as a main component.

14. The method according to claim 11, further comprising adjusting a frequency of the resonator by radiating a laser to the metal film from outside through the first bottom plate.

15. The method according to claim 11, wherein the resonance device further comprises a second substrate including:
a second bottom plate configured to have a second gap to the vibration part in the thickness direction, and
a second side wall extending from a circumferential edge of the second bottom plate toward the frame,
wherein the tip-end-side portion includes a third face that includes silicon facing the second bottom plate, and
wherein the adjusting the frequency of the resonator includes exciting the resonator to cause the tip-end-side portion to contact the second bottom plate.

16. The method according to claim 15, wherein the second bottom plate includes a fourth surface that comprises a silicon oxide and that faces the tip-end.

17. A resonance device comprising:
a resonator including:
a vibration part,
a frame disposed at at least a portion of a circumference of the vibration part, and
a supporting arm configured to connect the vibration part to the frame;
a first substrate including:
a first bottom plate configured to have a first gap to the vibration part in a thickness direction,
wherein the vibration part includes at least a vibration arm configured to vibrate in the first gap with an open-end side of the vibration arm moving in the first gap,
wherein the vibration arm includes a tip-end with a base-end-side portion and a tip-end-side portion that is closer to the open-end side of the vibration arm than the base-end-side portion, the base-end-side portion having a first surface that includes a metal film facing the first bottom plate, and the tip-end-side portion has a second surface that includes silicon facing the first bottom plate.

18. The resonance device according to claim 17, further comprising a second substrate including:
a second bottom plate configured to have a second gap to the vibration part in the thickness direction,
wherein the tip-end-side portion includes a third surface that includes silicon and that faces the second bottom plate.

19. The resonance device according to claim 18, wherein
a first gap thickness between the tip-end-side portion and the first bottom plate in the thickness direction is smaller than a second gap thickness between the tip-end-side portion and the second bottom plate in the thickness direction.

20. The resonance device according to claim 18, wherein the second bottom plate includes a fourth surface that includes a silicon oxide and that faces the tip-end.
